(19) United States
(12) Patent Application Publication
(10) Pub. No.: US 2025/0331317 A1
(43) Pub. Date: Oct. 23, 2025

(54) SEMICONDUCTOR DEVICE, METHOD OF MANUFACTURING SEMICONDUCTOR DEVICE, SOLAR CELL, AND METHOD OF MANUFACTURING SOLAR CELL

(71) Applicant: National Institute of Advanced Industrial Science and Technology, Tokyo (JP)

(72) Inventors: Kikuo MAKITA, lbaraki (JP); Hidenori MIZUNO, lbaraki (JP)

(21) Appl. No.: 18/873,054

(22) PCT Filed: May 1, 2023
(86) PCT No.: PCT/JP2023/017032

§ 371 Date: Dec. 9, 2024

(30) Foreign Application Priority Data
Jun. 14, 2022 (JP) 2022-095367

(51) Int. Cl. H10F 19/90; H10F 19/40; H10F 77/124; H10F 77/166; H10K 30/50; H10K 39/00; H10K 39/15; H10K 39/18; H10K 85/50

(52) U.S. Cl. CPC H10F 19/906; H10F 19/40; H10F 77/1248; H10F 77/1662; H10K 30/50; H10K 39/15; H10K 39/18; H10K 39/601; H10K 85/50

(57) ABSTRACT

A semiconductor device and a solar cell each having a bonding structure improving reliability of the semiconductor device or the solar cell and a method of manufacturing the same are provided. A semiconductor device or a solar cell includes: a first semiconductor element SB1 including a silicon layer and having a first bonding surface; a second semiconductor element SB2 having a second bonding surface facing the first bonding surface; and a plurality of electrically-conductive nanoparticles 23 positioned between the first bonding surface and the second bonding surface and electrically connecting the first semiconductor element SB1 and the second semiconductor element SB2 to each other, and the plurality of electrically-conductive nanoparticles 23 intrude into the silicon layer. In addition, a method of manufacturing a semiconductor device or a solar cell includes: a step of preparing a first semiconductor element SB1 and a second semiconductor element SB2; a step of arranging a plurality of electrically-conductive nanoparticles 23 on a first bonding surface of the first semiconductor element SB1; a step of intruding the plurality of electrically-conductive nanoparticles 23 into the silicon layer; and then, a step of facing and pressing the second bonding surface to and against the first bonding surface through the plurality of electrically-conductive nanoparticles 23 therebetween.

### CROSS-REFERENCE TO RELATED APPLICATIONS

This application is a National Stage application of International Patent Application No. PCT/JP2023/017032, filed on May 1, 2023, which claims priority to Japanese Patent Application No. 2022-095367, filed Jun. 14, 2022, each of which is hereby incorporated by reference in its entirety.

### TECHNICAL FIELD

The present invention relates to a semiconductor device and a method of manufacturing the same and a solar cell and a method of manufacturing the same, and relates to a technique effectively applied to, for example, a bonding layer used to stack a plurality of solar cells.

### BACKGROUND

As semiconductor devices, semiconductor devices in each of which a first semiconductor element and a second semiconductor element respectively made of different semiconductor materials are stacked while being electrically connected to each other has been known. An example of such a semiconductor device is a multi-junction solar cell. The multi-junction solar cell is a solar cell capable of achieving a higher performance by stacking a plurality of cells. For example, a multi-junction solar cell in which a high-efficiency GaAs-based solar cell is used as a top cell (on the light receiving side) while a low-cost Si-based solar cell is used as a bottom cell (on the non-light receiving side) has been expected as a solar cell capable of achieving a high efficiency and a low cost. And, examples of a method of manufacturing it include a method of stacking the top cell and the bottom cell by using a crystal growth technique and a method of mechanically stacking them by using a bonding technique (a mechanical stack method).

An example of the mechanical stack method is a bonding technique (hereinafter referred to as a smart stack technique) of bonding the top cell and the bottom cell to each other through electrically-conductive nanoparticles of Pd or the like arrayed on a bonding interface (Patent Document 1 and Non-Patent Document 1). In addition, surface process of a bonding surface has been further studied for this smart stack technique (Non-Patent Documents 2 and 3).
Patent Document 1: Japanese Patent Application No. 5875124
Non-Patent Document 1: H. Mizuno, et al., Japanese Journal of Applied Physics 55, 025001 (2016)
Non-Patent Document 2: K. Makita, et al., 35th European Photovoltaic Solar Energy Conference and Exhibition, (2018), p 20-22.
Non-Patent Document 3: K. Makita, et al., Progress in Photovoltaics, Research and Applications, 28, (2020), p 16-24.

### SUMMARY

### Problems to be Solved by the Invention

In the smart stack technique described in the above-described documents and the like, the top cell and the bottom cell are electrically connected to each other by the electrically-conductive nanoparticles. However, a cell performance and a quality of a semiconductor device depend on a bonding structure, and therefore, the bonding structure is important, and leads to respective reliabilities of the semiconductor device and the solar cell. An objective of the present invention is to provide a semiconductor device and a solar cell each having a bonding structure improving reliability of the semiconductor device or the solar cell and to provide a method of manufacturing the same.

### Means for Solving the Problems

To solve the above-described problems, the present inventors have vigorously made studies, and consequently, have found that the electrical connection between the first semiconductor element and the second semiconductor element is improved by intrusion of the electrically-conductive nanoparticles which electrically connect the first semiconductor element and the second semiconductor element to each other into a silicon layer of the first semiconductor element, and that the bonding structure is stabled by it. This also leads to improvements in the cell performance and the quality of the semiconductor device. Specifically, the following configurations have been adopted.
(1) A semiconductor device according to one embodiment is a semiconductor device including: a first semiconductor element including a silicon layer and having a first bonding surface; a second semiconductor element having a second bonding surface facing the first bonding surface; and a plurality of electrically-conductive nanoparticles positioned between the first bonding surface and the second bonding surface and electrically connecting the first semiconductor element and the second semiconductor element to each other, and the plurality of electrically-conductive nanoparticles intrude into the silicon layer.
(2) In addition, a solar cell according to one embodiment is a solar cell including the semiconductor device according to (1) described above, the silicon layer of the first semiconductor element contains a semiconductor material made of crystalline silicon or amorphous silicon, and the second semiconductor element contains one or more of semiconductor materials made of GaAs, AlGaAs, InGaP, InGaAsP, AlGaInP, InGaAs, a chalcogenide-based material, a perovskite-based material, and an organic-based material.
(3) A method of manufacturing a semiconductor device according to one embodiment is a method of manufacturing a semiconductor device, the method including: a step (a) of preparing a first semiconductor element including a silicon layer and having a first bonding surface; a step (b) of preparing a second semiconductor element having a second bonding surface; a step (c) of arranging a plurality of electrically-conductive nanoparticles on the first bonding surface; a step (d) of intruding the plurality of electrically-conductive nanoparticles into the silicon layer after the step (c); and a step (e) of facing and pressing the second bonding surface to and against the first bonding surface through the plurality of electrically-conductive nanoparticles therebetween after the step (d).
(4) In addition, a method of manufacturing a solar cell according to one embodiment is a method of manufacturing a solar cell including the method of manufacturing the semiconductor device according to (3) described above, a semiconductor material made of crystalline silicon or amorphous silicon is used as the silicon layer of the first semiconductor element, and one or more of semiconductor materials made of GaAs, AlGaAs, InGaP, InGaAsP, AlGaInP, InGaAs, a chalcogenide-based material, a perovskite-based material, and an organic-based material are used as the second semiconductor element.

### Effects of the Invention

The one embodiment can provide a semiconductor device and a solar cell each having a bonding structure improving reliability of the semiconductor device or the solar cell, and a method of manufacturing the same.

### BRIEF DESCRIPTIONS OF THE DRAWINGS

FIG. 1 is a configuration diagram of a semiconductor device (multi-junction solar cell) according to the present embodiment.

FIG. 2 is a schematic view for explaining a method of manufacturing the multi-junction solar cell.

FIG. 3 is a diagram for explaining a principle of a metal assisted chemical etching (MACE) method.

FIG. 4 is a configuration diagram of a multi-junction solar cell according to another first embodiment (example).

FIG. 5 is a configuration diagram of a multi-junction solar cell according to another second embodiment.

FIG. 6 is a configuration diagram of a multi-junction solar cell according to another third embodiment.

FIG. 7 is a configuration diagram of a multi-junction solar cell according to another example.

FIG. 8 is a configuration diagram of a multi-junction solar cell according to another example.

FIG. 9 is a diagram illustrating a relationship between a voltage and a current density of the multi-junction solar cell.

FIG. 10 is atomic force microscopic (AFM) photographs of a MACE-processed Si surface of the multi-junction solar cell (working example).

FIG. 11 is atomic force microscopic photographs of a MACE-not-processed Si surface (A) and a BHF-processed Si surface (B) of the multi-junction solar cell (comparative example).

FIG. 12 is respective photographs of multi-junction solar cells (samples A to C).

FIG. 13 is respective photographs provided after nitrogen blowing of the multi-junction solar cells (samples A to C).

FIG. 14 is a diagram illustrating a TEM image of the sample A and its analysis result by energy dispersive X-ray spectroscopy (TEM-EDX) (working example).

FIG. 15 is a diagram illustrating a TEM image of the sample B and its analysis result by energy dispersive X-ray spectroscopy (TEM-EDX) (comparative example).

### DETAILED DESCRIPTION

Hereinafter, embodiments of the present invention will be described in detail with reference to the drawings. Note that in the drawings, the same reference sign denotes the same or corresponding portions. Note that a numeral range described in this specification includes an upper limit and a lower limit.

### First Embodiment

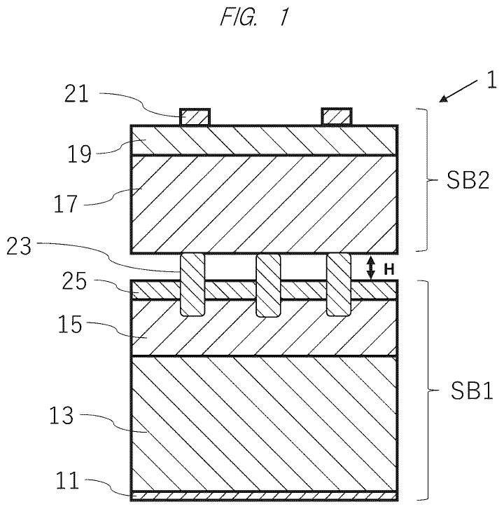

Although a technical idea in the present embodiment can be widely applied to a semiconductor device in which a first semiconductor element and a second semiconductor element respectively made of different semiconductor materials are stacked while being electrically connected to each other, this technical idea will be described below while exemplifying a solar cell. FIG. 1 is a configuration diagram of a semiconductor device (multi-junction solar cell) according to the present embodiment. In FIG. 1, a multi-junction solar cell 1 includes a solar cell element SB1 as the bottom cell and a solar cell element SB2 as the top cell. Here, the solar cell element SB1 is made of a silicon cell. On the other hand, the solar cell element SB2 is made of a GaAs cell. The multi-junction solar cell is a solar cell obtained by combining cells respectively having different properties, is made of a transparent “top cell” in an upper layer on which sunlight is directly incident and a “bottom cell” in a lower layer, and has an advantage of being able to utilize light having a wide wavelength by combining different materials to increase a conversion efficiency. Note that in the specification, the solar cell element may be merely referred to as a cell.

The solar cell element SB1 as the bottom cell includes a p-type silicon substrate 13 on which a p-type electrode 11 is formed and an n-type silicon layer 15 formed on the p-type substrate 13. Then, the solar cell element SB2 as the top cell includes a p-type GaAs layer 17 functioning as a light absorption layer, an n-type GaAs layer 19 formed on the p-type GaAs layer 17, and an n-type electrode 21 formed on the n-type GaAs layer 19. The solar cell element SB1 and the solar cell element SB2 are bonded to each other by a plurality of electrically-conductive nanoparticles 23, as illustrated in FIG. 1. As a result, the solar cell element SB1 and the solar cell element SB2 are mechanically bonded to each other and are electrically connected to each other. For example, nanoparticles made of palladium (Pd) can be used as the electrically-conductive nanoparticles 23.

When the solar cell element SB2 in this multi-junction solar cell 1 is irradiated with sunlight including visible light and infrared light from above, the n-type GaAs layer 19 as a component of the solar cell element SB2 is irradiated with the sunlight, and the sunlight is incident on the n-type GaAs layer 19 and the p-type GaAs layer 17 positioned in a layer below the n-type GaAs layer 19. At this time, the n-type GaAs layer 19 and the p-type GaAs layer 17 each have a band gap of 1.42 eV, and therefore, absorb light having a light energy equal to or more than 1.42 eV in the sunlight. Specifically, electrons in a valence band of the GaAs layers (the n-type GaAs layer 19 and the p-type GaAs layer 17) receive the light energy supplied from the sunlight, and are excited to a conduction band. Thus, the electrons are accumulated in the conduction band, and holes are generated in the valence band. In this way, the solar cell element SB2 is irradiated with the sunlight, the electrons are excited to the conduction band of the GaAs layer while the holes are generated in the valence band of the GaAs layer by the light having the light energy equal to or more than 1.42 eV in the sunlight. And, the conduction band of the n-type GaAs layer 19 which forms one of p-n junction portions is electronically lower in energy than the conduction band of the p-type GaAs layer 17 which forms the other p-n junction portion. Accordingly, the electrons excited to the conduction band move to the n-type GaAs layer 19, and the electrons are accumulated in the n-type GaAs layer 19. On the other hand, the holes in the valence band move to the p-type GaAs layer 17, and the holes are accumulated in the p-type GaAs layer 17. As a result, an electromotive force (V1) is generated between the p-type GaAs layer 17 and n-type GaAs layer 19.

On the other hand, light having a light energy less than 1.42 eV in the sunlight is not absorbed by the GaAs layers, but is transmitted through the GaAs layers. Thus, in FIG. 1, the light having the light energy less than 1.42 eV in the sunlight is incident on the solar cell element SB1 arranged in the layer below the solar cell element SB2. At this time, the n-type silicon layer 15 and the p-type silicon layer 13 each have a band gap of 1.12 eV, and therefore, absorb light having a light energy that is less than 1.42 eV and equal to or more than 1.12 eV in the sunlight. Specifically, electrons in a valence band of the silicon layers (the n-type silicon layer 15 and p-type silicon substrate 13) receive the light energy supplied from the sunlight, and are excited to a conduction band. Thus, the electrons are accumulated in the conduction band, and holes are generated in the valence band. In this way, when the solar cell element SB1 is irradiated with the sunlight, the electrons are excited to the conduction band of the silicon layers while the holes are generated in the valence band of the silicon layers by the light having the light energy that is less than 1.42 eV and equal to or more than 1.12 eV. As a result, the holes are accumulated in the p-type silicon substrate 13 while the electrons in the conduction band are accumulated in the n-type silicon layer 15. As a result, an electromotive force (V2) is generated between the p-type silicon substrate 13 and the n-type silicon layer 15.

Here, the solar cell element SB1 and the solar cell element SB2 are connected in series by the plurality of electrically-conductive nanoparticles 23. That is, the solar cell element SB1 and the solar cell element SB2 are connected in series. As a result, an electromotive force as a combination of the electromotive force (V1) and the electromotive force (V2) is generated in the multi-junction solar cell 1 made of the solar cell element SB1 and the solar cell element SB2 that are connected in series. And, for example, when a load is connected between the n-type electrode 21 and the p-type electrode 11, electrons flow from the n-type electrode 21 to the p-type electrode 11 through the load. In other words, a current flows from the p-type electrode 11 to the n-type electrode 21 through the load. When the multi-junction solar cell 1 is operated as described above, the load can be driven.

And, according to the multi-junction solar cell 1, light having a small light energy in addition to light having a large light energy in sunlight can be absorbed, and can be converted into an electrical energy, and therefore, a photoelectric conversion efficiency can be improved. That is, the multi-junction solar cell 1 can also use the light having the small light energy that cannot be used in a single solar cell, and therefore, is excellent in that a sunlight utilization efficiency can be improved.

Next, the features of the multi-junction solar cell 1 according to the present embodiment will be described. This multi-junction solar cell 1 has a feature of having a bonding structure in which the electrically-conductive nanoparticles 23, which bond the solar cell element SB1 and the solar cell element SB2 to each other, are intruded into a silicon layer that is the n-type silicon layer 15 in this example. This achieves functions and effects of both an electrical conductivity and a mechanical bonding strength in the bonding between the solar cell element SB1 and the solar cell element SB2. A structure of the multi-junction solar cell will be described in detail below.

### (Solar Cell Element SB1)

The solar cell element SB1 includes the p-type silicon substrate 13 on which the p-type electrode 11 is formed and the n-type silicon layer 15 formed on the p-type silicon substrate 13, and is also referred to as a silicon cell. The p-type electrode 11 is made of, for example, a silver film or an aluminum film. The bottom cell is preferably made of inexpensive silicon (silicon cell) that absorbs a long wavelength band. For example, there are single crystalline silicon, poly crystalline silicon, microcrystalline silicon, amorphous silicon and the like. And, the solar cell element SB1 has a band gap of, for example, 1.12 eV, and absorbs light having a light energy equal to or more than 1.12 eV in sunlight.

The solar cell element SB1 is manufactured by the following method. First, the p-type silicon substrate 13 is prepared. Then, after a surface of the p-type silicon substrate 13 is washed, the n-type silicon layer 15 is formed on one side surface of the p-type silicon substrate 13 by, for example, a thermal diffusion method or an ion implantation method. In this case, an oxidization region 25 (SiO2) of about 1 nm to 20 nm is formed on the whole or a part of a surface of the n-type silicon layer 15 by a high-temperature process in the thermal diffusion or by an annealing thermal process for activating a dopant material implanted by the ion implantation method. Finally, the p-type electrode 11 is formed by, for example, a sputtering method to form a layer structure as illustrated in FIG. 1.

### (Solar Cell Element SB2)

The solar cell element SB2 includes the p-type GaAs layer 17, the n-type GaAs layer 19 formed on the p-type GaAs layer 17, and the n-type electrode 21 formed on the n-type GaAs layer 19. The n-type electrode 21 is made of, for example, an alloy film such as AuGeNi/Au or TiAu/Au. The top cell may be made of not a high-efficiency GaAs cell that absorbs a short wavelength band but a CIGS (Cu, In, Ga, Se) layer (CIGS-based cell), an InGaP layer (InGaP-based cell), or the like. In the solar cell element SB2, for example, the GaAs cell has a band gap of 1.42 eV, and absorbs light having a light energy equal to or more than 1.42 eV in sunlight. The solar cell element SB2 is manufactured by the following method. First, the stacked

structure of the solar cell element SB2 made of the p-type GaAs layer 17, the n-type GaAs layer 19 and the like is formed on a GaAs substrate (not illustrated), a surface of which was washed, by using a general process. The stacked structure can be formed by using, for example, a crystal growth method such as a metal organic chemical vapour deposition (MOCVD) method or a molecular beam epitaxy (MBE) method. Then, the n-type electrode 21 is formed on the n-type GaAs layer 19 by an electron-beam vapor deposition method. Note that the method of forming the n-type electrode 21 may be another method. For example, a DC magnetron sputtering method, a resistance heating vapor deposition method, a screen printing method, an electrodeposition coating method, or the like may be used. The n-type electrode 21 is processed to have a grid pattern to ensure a region that can transmit light. Then, the solar cell element SB2 is separated from the GaAs substrate by using an ELO (epitaxial lift off) method. Thus, the stacked structure of the solar cell element SB2 can be formed. In this way, an interface as the bonding surface is formed in the solar cell element SB2. The interface is a surface separated from the GaAs substrate by the ELO method, and therefore, is surely flattened to be suitable for the bonding by the electrically-conductive nanoparticles 23. Note that the above-described solar cell element SB1 and solar cell element SB2 may be manufactured by not the above-described method but a publicly-known method. In addition, either one of the solar cell element SB1 and the solar cell element SB2 may be manufactured first.

### (Electrically-Conductive Nanoparticles 23)

The electrically-conductive nanoparticles 23 electrically connect the solar cell element SB1 and the solar cell element SB2 to each other. The electrically-conductive nanoparticles 23 are intruded into the n-type silicon layer 15 of the solar cell element SB1, and are stably held therein. As the electrically-conductive nanoparticles 23, any of metal nanoparticles of not palladium but gold, silver, platinum, nickel, aluminum, indium, zinc, copper, and the like, indium oxide, and zinc oxide may be used. Each diameter size of the electrically-conductive nanoparticles 23 is preferably 10 to 500 nm, and more preferably 10 to 100 nm, in consideration of a good electrical conductivity, suppression of light absorption/scattering by nanoparticles, and the like. In addition, a distance between the electrically-conductive nanoparticles 23 can be set to two times or more and ten times or less of the average diameter of the electrically-conductive nanoparticles 23. In this manner, the electrical conductivity based on the plurality of electrically-conductive nanoparticles 23 can be ensured, and the transparency in the bonding portion can be sufficiently ensured.

In addition, each shape of the electrically-conductive nanoparticles 23 is only necessary to ensure the electrical conductivity, and is not limited to, for example, a spherical shape but also a columnar shape such as a square columnar shape or a circular columnar shape, a fine line shape, a fibrous shape, an indefinite shape, or the like. Each shape of the electrically-conductive nanoparticles 23 can be controlled by, for example, adjusting a composition of a block copolymer described below or the like. And, in the multi-junction solar cell 1 according to the present embodiment, since the electrically-conductive nanoparticles 23 are intruded into the n-type silicon layer 15 of the solar cell element SB1, the electrical connection between the solar cell element SB1 and the solar cell element SB2 is improved, and the stable bonding structure that is excellent in the bonding strength is achieved. Therefore, according to the present embodiment, the solar cell having both the bonding strength and the good cell property can be provided.

### (Method of Bonding Between Solar Cell Element SB1 and Solar Cell Element SB2)

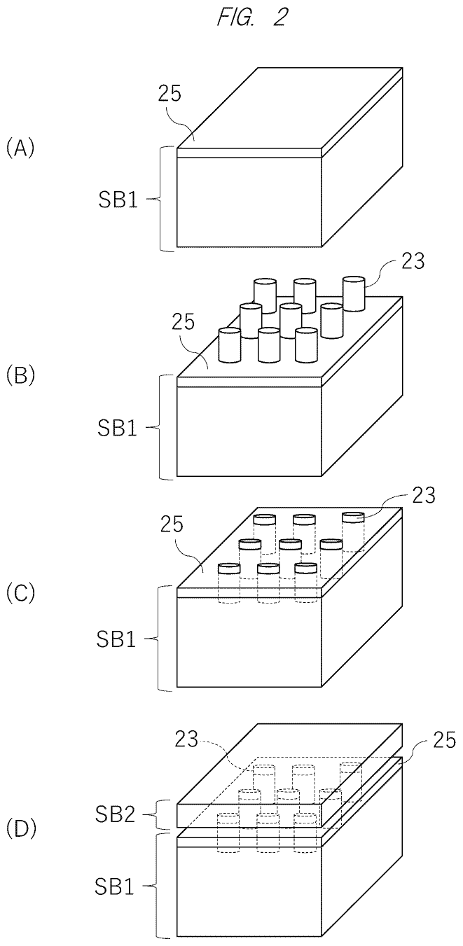

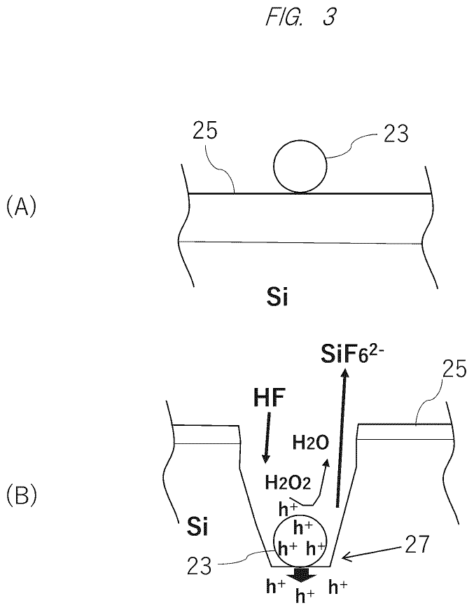

A method of bonding between the solar cell element SB1 and the solar cell element SB2 will be described with reference to FIGS. 2 and 3. The array of the electrically-conductive nanoparticles 23 is formed as illustrated in FIG. 2(B) by forming a microarray pattern of the electrically-conductive nanoparticles 23 first while using the block copolymer in accordance with the general normal smart stack technique, and then, processing it with a chloride solution to precipitate the electrically-conductive nanoparticles 23, and processing it with an argon plasma. An example is described below. A thin film (not illustrated) made of the block copolymer is formed on a surface of the solar cell element SB1 (the surface of the n-type silicon layer 15) as one of bonding targets. Specifically, the block copolymer made of polystyrene as a hydrophobic moiety dissolved in an organic solvent such as toluene or ortho-xylene and poly-2-vinylpyridine as a hydrophilic moiety is applied to the surface of the n-type silicon layer 15 by using a spin coating method or a dip coating method. Thus, a poly-2-vinylpyridine block is patterned on the surface of the n-type silicon layer 15 due to phase separation of the block copolymer. That is, a hydrophilic domain region is formed on the surface of the n-type silicon layer 15. Next, the solar cell element SB1 is immersed in an aqueous solution obtained by dissolving a metal ion salt typified by Na2PdCl4. Thus, a metal ion (Pd2+) can be taken into the pattern made of the poly-2-vinylpyridine block by a chemical interaction with pyridine. That is, the metal ion (Pd2+) is selectively precipitated in the above-described hydrophilic domain region. Then, after being sufficiently washed with water, the solar cell element SB1 is subjected to removal process of the block copolymer and reduction process of the metal ions by, for example, using an argon plasma. As a result, the array of the orderly-arranged electrically-conductive nanoparticles 23 can be formed while the pattern is retained (FIG. 2(B)). Note that each shape of the electrically-conductive nanoparticles 23 can be controlled by changing a degree of polymerization of the block copolymer. For example, when the degree of polymerization is set to “polystyrene:poly-2-vinylpyridine=133000:132000”, the diameter size of the electrically-conductive nanoparticles is 50 nm. However, when the degree of polymerization is set to “polystyrene:poly-2-vinylpyridine=135000:53000” in which the amount of the poly-2-vinylpyridine is smaller, the diameter size of the electrically-conductive nanoparticles can be controlled to be as small as 25 nm.

Next, when the entire solar cell element SB1 is immersed in an etchant (e.g., hydrogen peroxide (H2O2)/hydrogen fluoride (HF) solution), only a portion in contact with the electrically-conductive nanoparticles 23 is selectively eroded (also referred to as etched), and the electrically-conductive nanoparticles 23 settle down and penetrate the oxidation region 25 to be intruded into the n-type silicon layer 15 as illustrated in FIG. 2(C). Note that the etchant may be dropped on and applied to the surface of the solar cell element SB1, instead of the immersion. This method is referred to as a metal assisted chemical etching (MACE) method, and its principle is illustrated in FIG. 3. Note that FIG. 3 is a schematic view for merely explaining the principle. As expressed by Formula (1) and Formula (2), electrons that can be formed by oxidation reaction of silicon (Si) and holes that can be formed by decomposition of the hydrogen peroxide react with each other through the electrically-conductive nanoparticles 23 as the electrically-conductive metals, to promote the oxidation reaction so that an etching region 27 is formed. Then, as expressed by Formula (3), silicon dioxide reacts with hydrogen fluoride, and is discharged as SiF6 that is an etch residue.

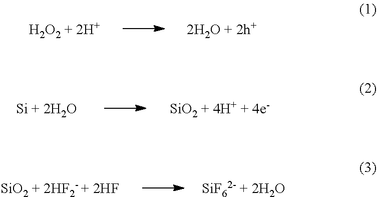

Then, after the solar cell element SB2 as the other bonding target is overlaid on the solar cell element SB1 in which the electrically-conductive nanoparticles 23 are arranged, the solar cell element SB1 and the solar cell element SB2 are bonded to each other by appropriate pressurization process (for example, 5 N/cm2) (FIG. 2(D)). In this way, the bonding between the solar cell element SB1 and the solar cell element SB2 is achieved by the electrically-conductive nanoparticles 23.

When the multi-junction solar cell made of the silicon cell and the GaAs cell is manufactured by the general smart stack technique, a junction resistance between the cells is particularly increased by the presence of the oxidation region on the surface of the silicon cell, and there is the problem of its influence on the solar cell as disclosed in Non-Patent Documents 2 and 3. However, according to the present embodiment, since the electrically-conductive nanoparticles 23 penetrate the oxidation region 25 to be intruded into the n-type silicon layer 15 having the low resistance on the lower side, the junction resistance between the cells is not affected by the oxidation region 25 and can be improved. Particularly, by the MACE method, only the region in contact with the electrically-conductive nanoparticles 23 is selectively eroded, and therefore, the electrically-conductive nanoparticles 23 can be easily intruded into the n-type silicon layer 15. Thus, the stable bonding structure that is excellent in the bonding strength is formed by so-called anchor effect of the electrically-conductive nanoparticles 23. Therefore, respective reliabilities of the semiconductor device and the solar cell can be improved.

In addition, in the MACE method (also referred to as MACE process), a settle-down height of the electrically-conductive nanoparticles 23 can be adjusted by controlling a process time period (immersion time period) with the etchant, an etchant liquid volume, an etchant composition (for example, a molar ratio between H₂O₂ and HF), and an etchant concentration. For example, a range of the etching region 27 is increased (deepened) by a long process time period or a high concentration of the H₂O₂/HF solution. Although the oxidation region 25 is partially etched by only the H₂O₂/HF solution, a region directly below the electrically-conductive nanoparticles of Pd or the like is selectively etched at high speed by the effect of the MACE. Then, the electrically-conductive nanoparticles 23 completely penetrate the oxidation region 25. At this time, the electrically-conductive nanoparticles 23 are desirably positioned at a depth of 5 nm or more in the n-type silicon layer 15.

In the smart stack technique, air or an adhesive is present at the bonding interface by being defined to the height of the electrically-conductive nanoparticles. Here, the air, the adhesive or the like has a low refractive index, and therefore, undesirably causes an optical loss due to light reflection at the bonding interface. However, since the electrically-conductive nanoparticles 23 are deeply intruded into the silicon cell, the effective thickness of the air or adhesive can be reduced to reduce the optical loss. For example, if a distance “H” (also referred to as a bonding gap in FIG. 1) between the solar cell element SB1 and the solar cell element SB2 is equal to or less than 20 nm, more preferably equal to or less than 10 nm, the optical reflection loss can be reduced to be equal to or less than 10%. This distance H corresponds to an exposure height of the electrically-conductive nanoparticles 23, and the optical loss can be reduced by controlling the exposure height. In addition, the distance H can also be effectively controlled by changing the shape, the size, or the density of the electrically-conductive nanoparticles 23. And, the deeper the settle-down height of the electrically-conductive nanoparticles 23 is, the larger the stability of the holding of the electrically-conductive nanoparticles 23 in the silicon layer is. Accordingly, the settle-down height of the electrically-conductive nanoparticles 23 is preferably controlled as deep as half of the entire height of the electrically-conductive nanoparticles 23 or more. In addition, the distance His preferably as close to 0 (zero) as possible, and can be set to 0 (zero).

### Second Embodiment

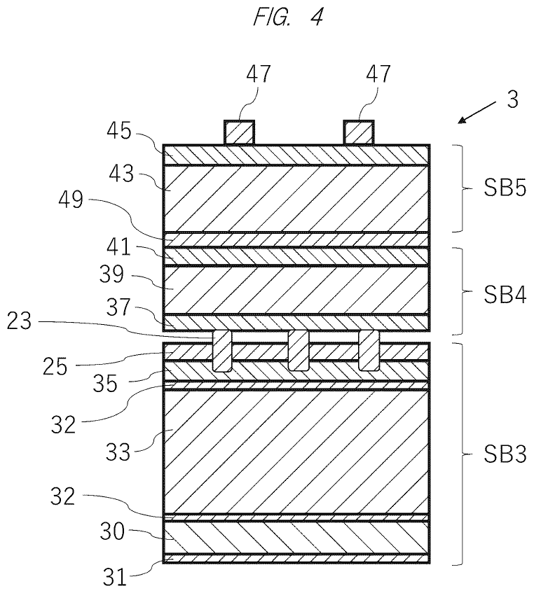

FIG. 4 is a configuration diagram of a semiconductor device (multi-junction solar cell) according to another embodiment. Although the multi-junction solar cell 1 illustrated in FIG. 1 is the solar cell made of two junctions of the silicon cell and the GaAs cell, the above-described bonding structure is also applicable to a solar cell made of three or more junctions. A multi-junction solar cell 3 illustrated in FIG. 4 includes a solar cell element SB3 as a bottom cell, a solar cell element SB4 as a middle cell, and a solar cell element SB5 as a top cell. The solar cell element SB3 is made of a silicon cell, the solar cell element SB4 is made of a GaAs cell, and the solar cell element SB5 is made of an InGaP cell. Specifically, the solar cell element SB4 and the solar cell element SB5 are respectively two junction elements of InGaP and GaAs, and the solar cell element SB3 is referred to as a TOPCon (tunnel oxide passivated contact) silicon cell and is a silicon cell in which a silicon layer (amorphous or polycrystalline silicon) as a contact layer is formed through a thin film oxide layer and which has a feature of a high efficiency with a reduced current loss.

The solar cell element SB3 includes, for example, a p-type silicon layer (amorphous or polycrystalline silicon) 30 on which a p-type electrode 31 made of an aluminum film or a silver film is formed, an SiOx tunnel layer 32 formed on the p-type silicon layer 30, a p-type silicon substrate 33 as a light absorption layer, an SiOx tunnel layer 32 formed on the p-type silicon layer 33, and an n-type silicon layer (amorphous or polycrystalline silicon) 35. In addition, an oxidation region 25 of about 10 nm is formed on the whole or a part of a surface of the n-type silicon layer 35 as similar to the multi-junction solar cell 1 (FIG. 1). In this way, the solar cell element SB3 is formed.

The solar cell element SB3 is manufactured by the following method. That is, the solar cell element SB3 is obtained by forming the thin-film tunnel layers (SiOx tunnel layers 32) each made of an SiOx oxide film on both sides of the p-type silicon substrate 33, the surface of which was washed, and then, forming the electrically-conductive polycrystalline or amorphous silicon layers (the p-type silicon layer 30 and the n-type silicon layer 35) on both surfaces thereof, and finally forming a silver film or an aluminum film as the p-type electrode 31 on a rear surface thereof.

And, the solar cell element SB4 includes a p-type GaAs layer 37 functioning as a contact layer, a p-type GaAs layer 39 functioning as a light absorption layer formed on the p-type GaAs layer, and an n-type GaAs layer 41 formed on the p-type GaAs layer 39. In this way, the solar cell element SB4 is formed.

In addition, the solar cell element SB5 includes a p-type InGaP layer 43 functioning as a light absorption layer, an n-type InGaP layer 45 formed on the p-type InGaP layer 43, and an n-type electrode (for example, an alloy electrode of AuGeNi/Au or Ti/Au) 47 formed on the n-type InGaP layer 45. In this way, the solar cell element SB5 is formed. Here, the solar cell element SB4 and the solar cell element SB5 are formed on one semiconductor chip, and the solar cell element SB4 and the solar cell element SB5 are bonded to each other and also electrically connected in series by a tunnel layer 49 formed on the semiconductor chip. For example, the tunnel layer is made of a degenerate semiconductor layer sandwiched between the n-type GaAs layer 41 of the solar cell element SB4 and the p-type InGaP layer 43 of the solar cell element SB5. Thus, the n-type GaAs layer 41 of the solar cell element SB4 and the p-type InGaP layer 43 of the solar cell element SB5 are electrically connected to each other.

Note that the solar cell element SB4 and the solar cell element SB5 are manufactured by using a general process. That is, they are sequentially epitaxially grown on a GaAs substrate, a surface of which was washed, and then, are formed by separating a stacked structure of the solar cell element SB4 and the solar cell element SB5 from the GaAs substrate by an ELO method.

On the other hand, the solar cell element SB3 cannot be formed together with the solar cell element SB4 and the solar cell element SB5 by the crystal growth because of basically differing in crystal structure therefrom. Accordingly, the solar cell element SB3 is formed on a semiconductor substrate different from the semiconductor substrate on which the solar cell element SB4 and the solar cell element SB5 are formed.

Then, by the method illustrated in FIG. 2, the array of the electrically-conductive nanoparticles 23 is formed on the solar cell element SB3, and then, only a portion in contact with the electrically-conductive nanoparticles 23 is selectively eroded. Then, the semiconductor chip on which the solar cell element SB3 is formed and the semiconductor chip on which the solar cell element SB4 and the solar cell element SB5 are formed are overlaid with each other, and are subjected to pressurization process. Thus, the solar cell element SB3, the solar cell element SB4, and the solar cell element SB5 are mechanically bonded to one another, and are electrically connected to one another by the plurality of electrically-conductive nanoparticles 23. Here, the solar cell element SB3, the solar cell element SB4, and the solar cell element SB5 respectively have different band gaps. As described in the first embodiment, an electromotive force is generated in each of the solar cell elements, and an electromotive force that is the sum of the electromotive forces is generated in the entire multi-junction solar cell 3. The present embodiment can also provide a similar functional effect to that in the first embodiment.

### Third Embodiment

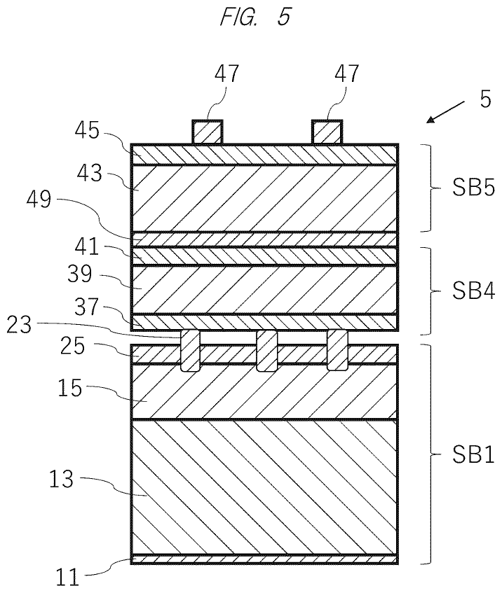

FIG. 5 is a configuration diagram of a semiconductor device (multi-junction solar cell) according to another embodiment. A multi-junction solar cell 5 includes a solar cell element SB1 as a bottom cell, a solar cell element SB4 as a middle cell, and a solar cell element SB5 as a top cell. The solar cell element SB1 is made of a silicon cell, the solar cell element SB4 is made of a GaAs cell, and the solar cell element SB5 is made of an InGaP cell. That is, the solar cell element SB1 has a similar configuration to that of the solar cell element SB1 of the multi-junction solar cell 1 illustrated in FIG. 1, and the solar cell element SB4 and the solar cell element SB5 respectively have similar configurations to those of the solar cell element SB4 and the solar cell element SB5 of the multi-junction solar cell 3 illustrated in FIG. 4, and therefore, descriptions thereof are omitted. The manufacturing of the solar cell element SB1, the solar cell element SB4, and the solar cell element SB5, the arraying of the electrically-conductive nanoparticles 23 on the solar cell element SB1 and the erosion of the contact portion by the electrically-conductive nanoparticles 23, the bonding of the solar cell element SB1 with the solar cell element SB4 and the solar cell element SB5, and the like are performed by the similar methods to those in the above-described embodiments. This point also applies to the following embodiments. The present embodiment can also provide the similar functional effect to that in the first embodiment or the like. Here, the solar cell element SB1 is referred to as back surface field (BSF) type silicon, and is a silicon cell achieving a high efficiency with reduced electron loss near the electrode when a side of the p-type silicon substrate 13, the side being closer to the p-type electrode 11, is formed as a p-type layer having a high concentration.

### Fourth Embodiment

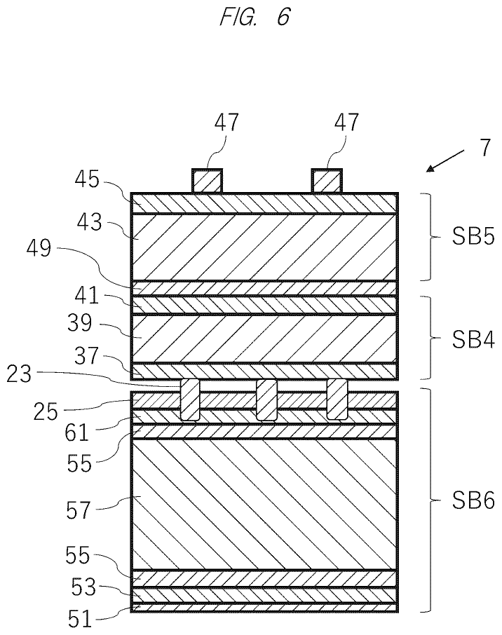

FIG. 6 is a configuration diagram of a semiconductor device (multi-junction solar cell) according to another embodiment. A multi-junction solar cell 7 includes a solar cell element SB6 as a bottom cell, a solar cell element SB4 as a middle cell, and a solar cell element SB5 as a top cell. The solar cell element SB6 is made of a silicon cell, the solar cell element SB4 is made of a GaAs cell, and the solar cell element SB5 is made of an InGaP cell.

The solar cell element SB6 includes, for example, a p-type amorphous silicon layer 53 on which a p-type electrode 51 made of an aluminum film, a silver film, or the like is formed, an i-type amorphous silicon layer 55 formed on the p-type amorphous silicon layer 53, an n-type silicon substrate 57 as a light absorption layer formed on the i-type amorphous silicon layer 55, an i-type amorphous silicon layer 55 formed on the n-type silicon substrate 57, and an n-type amorphous silicon layer 61 formed on the i-type amorphous silicon layer 55. In addition, an oxidation region 25 is formed on the whole or a part of a surface of the n-type amorphous silicon layer 61, as similar to the multi-junction solar cell 1 (FIG. 1). In this way, the solar cell element SB6 is formed.

The solar cell element SB6 is manufactured by the following method. That is, the solar cell element SB6 is obtained by forming the i-type amorphous silicon layers 55 on both sides of the n-type silicon substrate 57, a surface of which was washed, and then, forming the electrically-conductive amorphous silicon layers (the p-type amorphous silicon layer 53 and the n-type amorphous silicon layer 61) on both surfaces thereof, and finally forming the silver film or the aluminum film as the p-type electrode 51 on a rear surface thereof.

The solar cell element SB4 and the solar cell element SB5 respectively have similar configurations to those of the solar cell element SB4 and the solar cell element SB5 of each of the multi-junction solar cells 3 and 5 illustrated in FIGS. 4 and 5, and therefore, descriptions thereof are omitted. The present embodiment can also provide a similar functional effect to that in the first embodiment or the like. The solar cell element SB6 is referred to as a heterojunction with intrinsic thin-layer (HIT) silicon cell or a hetero junction technology (HJT) silicon cell, and is a silicon cell achieving a high efficiency with reduced current loss since the p-type amorphous silicon layer 53 and the n-type amorphous silicon layer 61 as the cell contact layer are formed through the i-type amorphous silicon layers 55 and the like. Note that a constituent material of the solar cell element as the top cell or the middle cell is not limited to GaAs, InGaP, or the like, and a material such as AlGaAs, InGaAsP, AlInGaP, InGaAs, a chalcogenide-based material (Cu (In, Ga) Se₂ (CIGS)), a perovskite-based material, and an organic-based material may be used. In addition, although the silicon cell as the bottom cell has a wide variety of structures, the top silicon layer as the bonding surface has in common that the oxidation region is formed, and it is obvious that this technique can be applied thereto.

### WORKING EXAMPLES

A multi-junction solar cell 3 illustrated in FIG. 4 was m by the following method. First, the solar cell element SB3 was manufactured by the following method. A surface of the p-type silicon substrate 33 was subjected to a surface process using a diluted hydrofluoric acid-based etchant, and then, the thin-film SiOx tunnel layer 32 of about 1 nm was formed on its both surfaces by a chemical oxidation method. Although the p-type silicon substrate 33 was immersed in a concentrated nitric acid solution to form the oxide film here, the oxidation is also achieved by a CVD method or the like. Then, the p-type silicon layer (amorphous) 30 and the n-type silicon (amorphous) layer 35 of 100 nm were formed by a chemical vapor deposition (CVD) method, and then, were annealed at 800° C. to poly-crystallize the amorphous layers. Finally, the aluminum film to be the p-type electrode 31 was formed to have a thickness of about 500 nm by a sputtering method. Note that the solar cell element SB3 was processed under a condition of a diameter of 4 inches and a thickness of 300 μm, was finally cut to about 1 cm square, and was used as the bottom cell. Next, the solar cell element SB4 and the solar cell element SB5 were manufactured by the following method. On the p-type GaAs substrate, a surface of which was washed with an ethanol solution, the p-type GaAs layer 37, the p-type GaAs layer 39, the n-type GaAs layer 41, the tunnel layer 49, the p-type InGaP layer 43, and the n-type InGaP layer 45 were sequentially formed through a release layer therebetween by a molecular beam epitaxy method (using a molecular beam epitaxy apparatus (Compact 21 solid source MBE) manufactured by Riber S.A.; a growth temperature of 550° C.), and then, the n-type electrode 47 made of AuGeNi/Au was formed using an electron-beam vapor deposition apparatus (SVC-700LEB/4G manufactured by Sanyu Electron Co., Ltd.; a film formation rate of 2 to 4 angstrom per second). Here, the release layer was required for peeling from the substrate in the ELO process, and an AlAs layer of 50 nm was applied thereto. The solar cell elements SB4 and SB5 were processed under a condition of a diameter of 2 inches and a thickness of about 350 μm (about 340 μm for the GaAs substrate), was finally cut into 4 mm square, and was applied as the top cell. The cut top cell was immersed in the HF solution (having a solution concentration of 20 mass %) for 12 hours, and was peeled from the GaAs substrate to obtain the element including the solar cells SB4 and SB5. Note that a total thickness of the peeled solar cell element SB4 and solar cell element SB5 was about 4 μm.

Next, the array of the electrically-conductive nanoparticles 23 was formed on the solar cell element SB3 by the following method. The Pd nanoparticles as the electrically-conductive nanoparticles 23 were arrayed on the solar cell element SB3 by thinning the polystyrene-poly-2-vinylpyridine as the block copolymer and using it as a template. That is, the solar cell element SB3 was spin-coated with a 0.5 mass % ortho-xylene solution of polystyrene-poly-2-vinylpyridine having a total molecular weight of 265000 g/mol (polystyrene molecular weight: 133000 g/mol, poly-2-vinylpyridine molecular weight: 132000 g/mol) to form the thin film. Next, the solar cell element SB3 was immersed in a 1-mM Na₂PdCl₄ aqueous solution for two minutes. After the washing with water, the solar cell element SB3 was subjected to the argon plasma process (processed at 50 W for two minutes using a plasma apparatus (Femto) manufactured by Diener Plasma GmbH&Co.), to array the Pd nanoparticles having an average size (diameter) of 50 nm not covered with organic molecules. An average array distance between the palladium nanoparticles in this array was 100 nm.

Next, the solar cell element SB3 was subjected to the MACE process to selectively erode only its portion in contact with the Pd nanoparticles, thereby settling down the Pd nanoparticles (see FIG. 2(C)). This process was performed by immersing the solar cell element SB3 with the arrayed Pd nanoparticles into the etchant (at 25° C.) for one minute while using the H₂O₂/HF solution (a solution ratio was set to “H₂0₂:HF:H₂0=1:1:10” under use of an H₂O₂ solution having a concentration of 30 mass % and an HF solution having a concentration of 50 mass %) as the etchant. Then, the entire solar cell element SB3 was washed with water to remove the etchant. Next, the solar cell element SB4 and the solar cell element SB5 were overlaid on the solar cell element SB3 with the arrayed Pd nanoparticles, and then, the resultant was weighted (at 5 N/cm²) using a weight at a room temperature for about two hours, thereby bonding the solar cell element SB3, the solar cell element SB4, and the solar cell element SB5 to one another. This solar cell was used as a sample A.

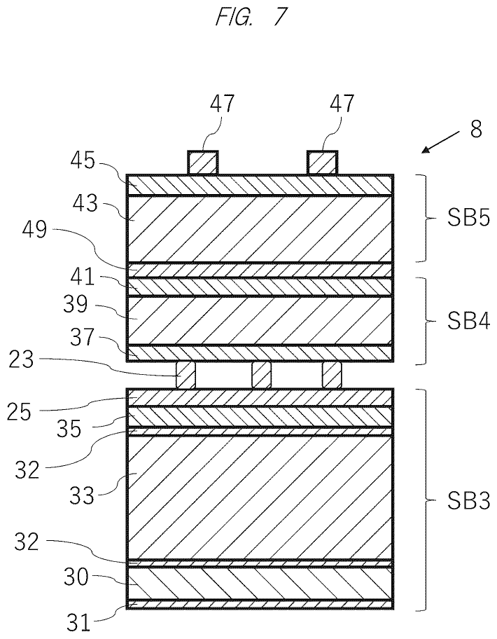

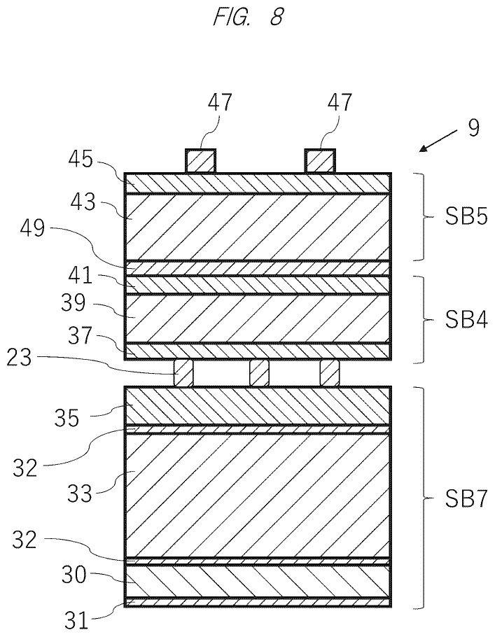

In addition, for comparison, a multi-junction solar cell 8 illustrated in FIG. 7 and a multi-junction solar cell 9 illustrated in FIG. 8 were also manufactured. The array of the electrically-conductive nanoparticles 23 (Pd nanoparticles) was formed (see FIG. 2(B)) on the multi-junction solar cell 8 (FIG. 7), and then, the multi-junction solar cell 8 was not subjected to the MACE process. The solar cell element SB4 and the solar cell element SB5 were overlaid on the solar cell element SB3 with the arrayed electrically-conductive nanoparticles 23, and then, the resultant was subjected to the pressurization process (at 5 N/cm²), thereby bonding the solar cell element SB3, the solar cell element SB4, and the solar cell element SB5 to one another. Other conditions were similar to those in the method of manufacturing the multi-junction solar cell 3. This solar cell was used as a sample B.

In addition, the multi-junction solar cell 9 (FIG. 8) was manufactured by the following method. It has been described above that the junction resistance between the cells is increased by the presence of the oxidation region on the surface of the silicon cell to affect the property of the solar cell. On the other hand, the multi-junction solar cell 9 was obtained by performing a process for removing the oxidation region. First, the solar cell element SB3, the solar cell element SB4, and the solar cell element SB5 were manufactured by a similar method to that in the case of the multi-junction solar cell 3. Next, before the formation of the array of the electrically-conductive nanoparticles 23 (Pd nanoparticles), the oxidation region 25 formed on the surface of the solar cell element SB3 was partially or entirely removed by using a buffered HF solution (a mixed solution of hydrofluoric acid and ammonium fluoride, which is also referred to as a BHF solution) (for a solar cell element SB7). Specifically, the solar cell element SB3 was immersed in a BHF solution (at 25° C.) for one minute by using the BHF solution (BHF63 manufactured by Daikin Industries, Ltd.) (BHF process).

Then, the washing with water was performed, and the array of the electrically-conductive nanoparticles 23 was formed by using a similar method to that in the case of the multi-junction solar cell 3 (see FIG. 2(B)). Then, the MACE process was not performed, and the solar cell element SB4 and the solar cell element SB5 were overlaid on the solar cell element SB3 with the arrayed electrically-conductive nanoparticles 23, and then, the resultant was subjected to the pressurization process (at 5 N/cm²), thereby bonding the solar cell element SB7, the solar cell element SB4, and the solar cell element SB5 to one another. This solar cell was used as a sample C.

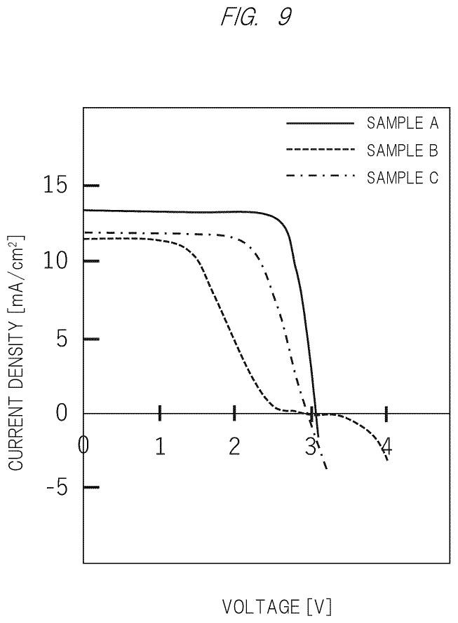

FIG. 9 illustrates each current-voltage property (I-V curve) of the solar cells as the samples A to C manufactured by the above-described methods. This measurement was performed with irradiation with AM (Air Mass)-1.5G simulated sunlight using an I-V simulator apparatus (Model 38A042Y manufactured by Bunkoukeiki Co., Ltd). In addition, Table 1 shows respective extraction results of a short-circuit current density (Jsc), an open-circuit voltage (V), a fill factor (%), and a power generation efficiency (%) of each of the samples A to C from the current-voltage property illustrated in FIG. 9.

TABLE 1
Measurement Results of Solar Cell Property

| | Sample A | Sample B | Sample C |
|---|---|---|---|
| Process | With MACE | Without MACE | With BHF |
| | process | process | process |
| Short-circuit current JSC | 13.2 | 12.0 | 12.2 |
| (mA/cm²) | | | |
| Open-circuit voltage (V) | 3.02 | 2.90 | 2.95 |
| Fill factor (%) | 80 | 55 | 78 |
| Power generation | 31.9 | 19.1 | 28.1 |
| efficiency (%) | | | |

The solar cells as the sample A and the sample C exhibit a result of good cell performance. Particularly, the solar cell as the sample A exhibits respective excellent cell properties in all items. Although the solar cell as the sample C was subjected to the BHF process, a part of the oxidation region conceivably remained, and therefore, its property possibly deteriorated. On the other hand, in the solar cell as the sample A, since the Pd nanoparticles penetrated the oxidation region to be intruded into the n-type silicon layer 35 by the MACE process, its electrical conductivity is good. Thus, the solar cell as the sample A had the sufficiently low junction resistance because of not being particularly affected by the oxidation region, and therefore, had the high power generation efficiency more than 30%. Also, its short-circuit current was 1 mA/cm² larger than those in the other samples. This is because the exposure height of the Pd nanoparticles was reduced by the MACE method to bring the distance (H) between the solar cell element SB3 and the solar cell element SB4 to be equal to or less than 10 nm, thereby reducing the reflection loss at the bonding interface. Thus, it was considered that this increases a photocurrent of the solar cell element SB3 as the sample A, and therefore, increases a current matching level as the multi-junction cell. On the other hand, the solar cell as the sample B had an S-curved shape because of being affected by the oxidation region 25 to increase the resistance of the bonding portion.

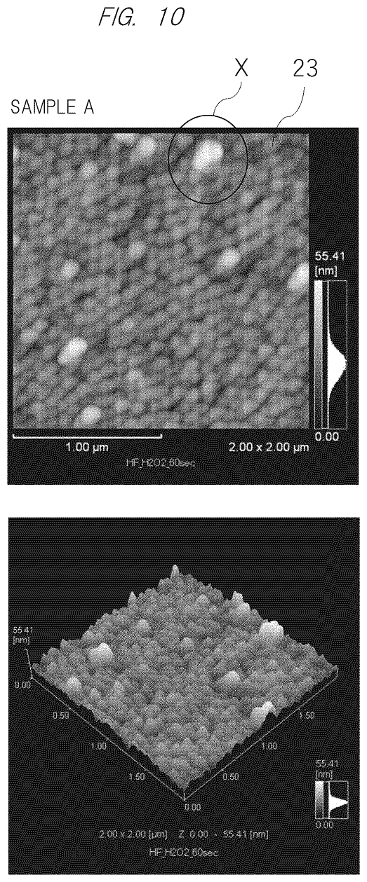

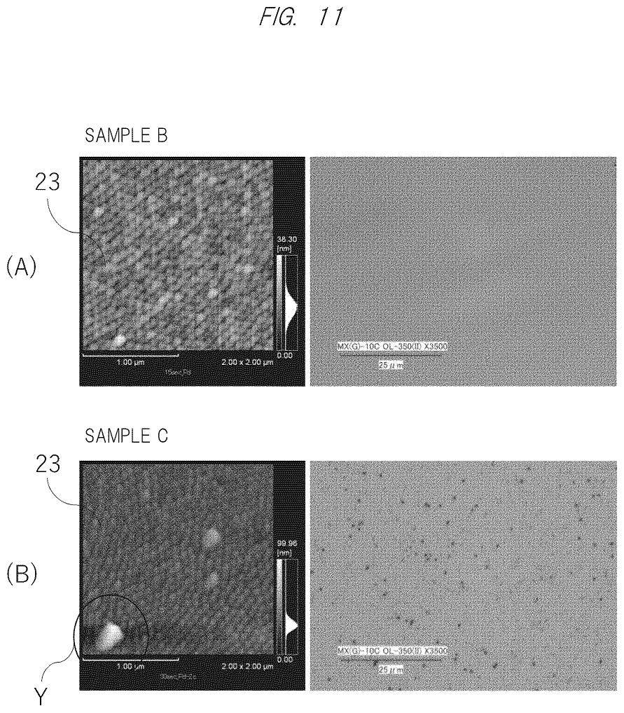

FIG. 10 illustrates atomic force microscope (AFM) photographs of the MACE-processed Si surface of the sample A. FIG. 10(A) illustrates the AFM photograph observed from its upper surface, and FIG. 10(B) illustrates the AFM photograph three-dimensionally displayed in its inclined-surface direction. FIG. 11(A) illustrates an AFM photograph (on a left side) and an optical microscope photograph (on a right side) of the Si surface of the sample B with the arrayed Pd nanoparticles, and FIG. 11(B) illustrates an AFM photograph (on a left side) and an optical microscope photograph (on a right side) of the Si surface of the sample C with the arrayed Pd nanoparticles. The atomic force microscopy was performed using a microscope (SPM9600 manufactured by SHIMADZU CORPORATION).

In the solar cell as the sample A (FIG. 10), the array of the electrically-conductive nanoparticles 23 (Pd nanoparticles) was clearly observed, and there was no significantly anomalous precipitation although the precipitation of the Pd nanoparticles was slightly observed (see an “X” portion) due to the influence of MACE the process. On the other hand, in the solar cell as the sample C (FIG. 11(B)), surface roughness or surface defect was formed on the silicon layer by the BHF process, and this formation inhibited the uniform array of the electrically-conductive nanoparticles 23 (Pd nanoparticles). Particularly, the surface defect was induced, thereby causing the anomalous precipitation of the Pd nanoparticles (see a “Y” portion) exceeding 100 nm in height. Here, in the MACE method (sample A), the process was performed after the electrically-conductive nanoparticles 23 were arrayed. Accordingly, a portion not including the electrically-conductive nanoparticles 23 is not ideally eroded while only a portion directly below the electrically-conductive nanoparticles 23 is uniformly eroded to cause the settle down. Therefore, overall smoothness of the electrically-conductive nanoparticles 23 was kept, and a degree of the surface roughness was made smaller than that in the case of the BHF process (sample C). Note that the solar cell as the sample B (FIG. 11(A)) was not subjected to the surface process such as BHF process or MACE process, and therefore, the array of the electrically-conductive nanoparticles 23 (Pd nanoparticles) was uniform.

Next, the solar cells as the samples A to C were observed in terms of appearance observation and observation with nitrogen blowing for comparison in terms of the bonding strength and the stability. First, in the appearance observation, a stereoscopic microscope was used. In addition, the observation with nitrogen blowing was performed by the following method. That is, a pointed pipe glass tube (1 mm in diameter) was prepared, and nitrogen gas (a pressure of 5 Kg/cm²) was blown onto the bonding portion of each of the samples through the glass tube for about five seconds. Table 2 shows each evaluation result of the solar cells as the samples A to C. Note that an item “solar cell performance” in Table 2 was determined from the results illustrated in Table 1.

TABLE 2
Evaluation of Solar Cells

| | Sample A | Sample B | Sample C |
|---|---|---|---|
| Process | With MACE | Without MACE | With BHF |
| | process | process | process |
| Bonding appearance | Without | Without abnormality | With Voids |
| | abnormality | | |
| Observation with nitrogen | Without peeling | Without peeling | With peeling |
| blowing | | | |
| Solar cell performance | Good | Property failure | Good |

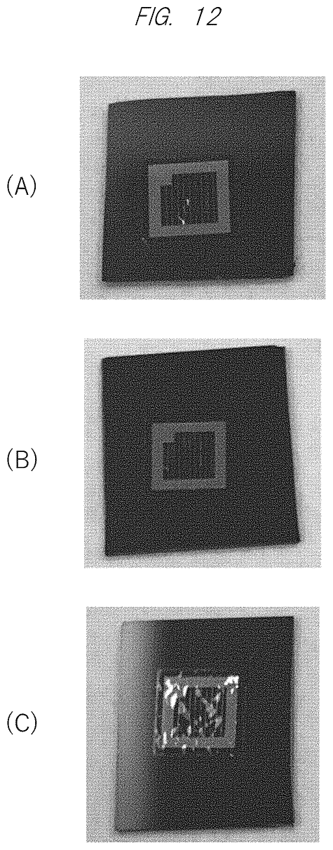

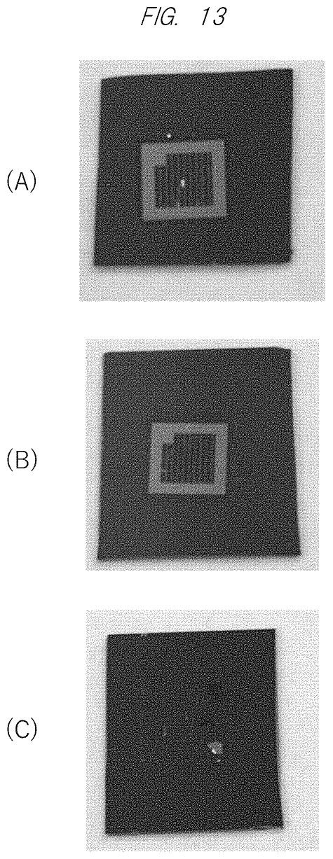

FIGS. 12(A) to 12(C) are the appearance photographs (of the upper surfaces) of the solar cells as the samples A to C. In the solar cells as the sample A (FIG. 12(A)) and the sample B (FIG. 12(B)), no abnormalities were respectively observed. On the other hand, in the solar cell as the sample C, as illustrated in FIG. 12(C), a floating unbonded portion (void) was observed, and a portion into which air was intruded was observed. In addition, in the solar cells as the sample A (FIG. 13(A)) and the sample B (FIG. 13(B)) in terms of the observation with nitrogen blowing, as illustrated in FIG. 13, no abnormalities were respectively observed. On the other hand, a damage such as scattering or peeling was caused in the solar cell as the sample C (FIG. 13(C)). The cells were bonded by the Pd nanoparticles, and, if the height of the Pd nanoparticles was uniform, the bonding strength was improved. However, in the sample C, the anomalous precipitation of the Pd nanoparticles was observed as illustrated in FIG. 11(B), and therefore, the decrease of the bonding strength is considered.

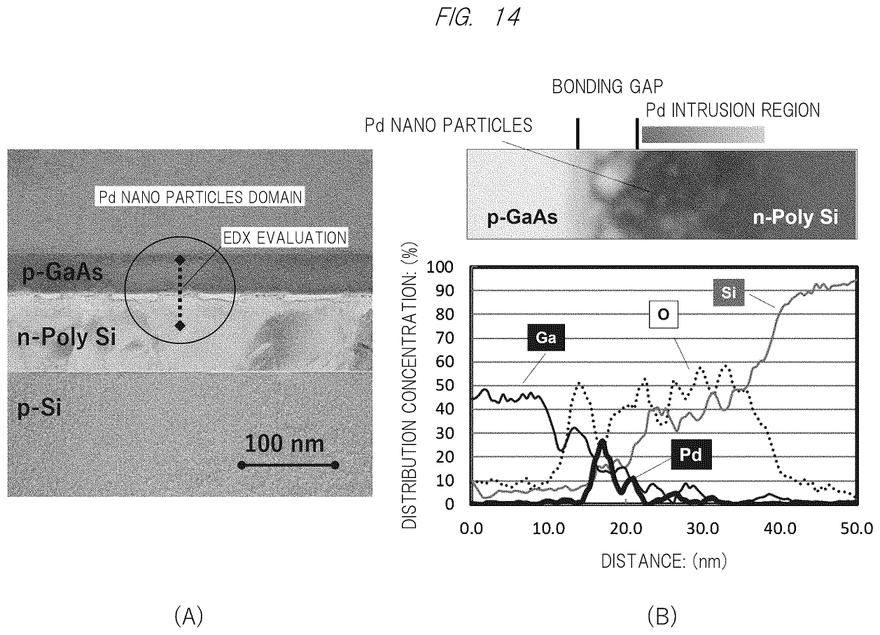

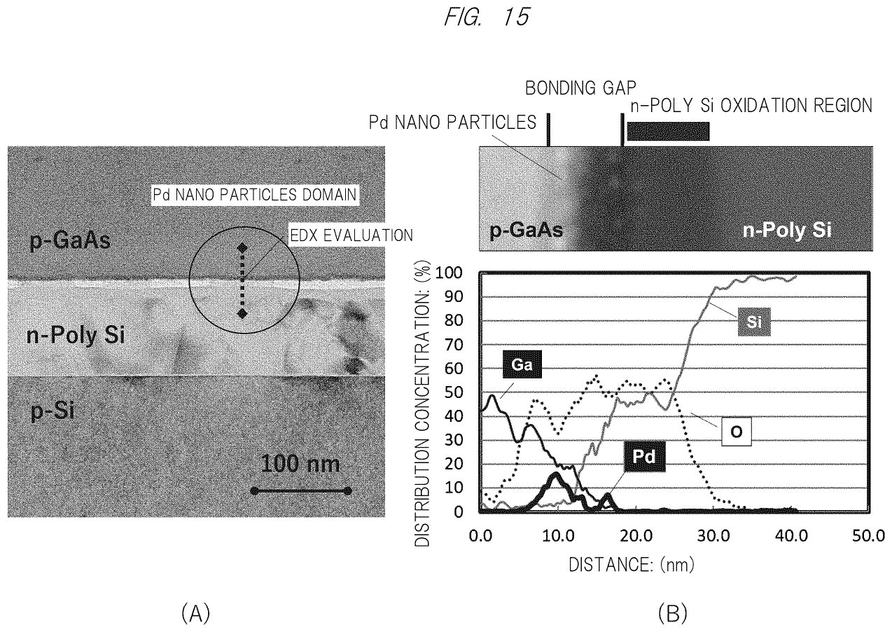

FIG. 14 illustrates a TEM (transmission electron microscope) image (A) of the sample A and an analysis result (B) based on energy dispersive X-ray spectroscopy. FIG. 15 illustrates a TEM image (A) of the sample B and an analysis result (B) based on energy dispersive X-ray spectroscopy. The TEM image was measured by a transmission electron microscope (H-9500 manufactured by Hitachi High-Tech Corporation; an acceleration voltage of 200 kV). In addition, the energy-dispersive X-ray spectroscopy was measured by an electron microscope (JEM-ARM200F manufactured by JEOL Ltd.; an acceleration voltage of 200 kV). As illustrated in FIG. 14, as a result of the magnifying observation on the Pd nanoparticles by the TEM, a domain structure with the aggregated Pd nanoparticles of about a few nanometers was observed. In the solar cell as the sample A, the intrusion state (of 10 nm or more) of the Pd nanoparticles forming the domain into the n-type silicon layer (polycrystalline) below the bonding gap (8 nm) was observed. Note that the surrounding oxidation region not including the Pd nanoparticles was directly etched by the HF:H₂O₂ solution at the time of the MACE process, but was conceivably microscopically left as a thin film.

And, in data of the sample A based on the energy dispersive X-ray spectroscopy, a Pd signal was also observed in the n-type silicon layer (polycrystalline), and the intrusion state of the Pd nanoparticles was confirmed. On the other hand, in the solar cell as the sample B, the oxidation region of about 10 nm in thickness included in the surface of the silicon cell was observed, and the fact that the Pd nanoparticles were not intruded into the n-type silicon layer (polycrystalline) but were present in only the bonding gap was observed. In the energy dispersive X-ray spectroscopy, the Pd signal was also observed in only the bonding gap as different from the sample A. In the sample C, the oxidation region was removed by the BHF process, but the Pd nanoparticles were observed only in the bonding gap, although not illustrated. In the sample A, because of the intrusion of the Pd nanoparticles into the n-type silicon layer (polycrystalline), the junction resistance was reduced because of not being affected by the oxidation region, and the bonding structure excellent in the bonding strength was formed by so-called anchor effect. In the sample B, the junction resistance was increased by the surface oxidation region of the silicon semiconductor, thereby deteriorating the cell performance. In the sample C, the oxidation region was removed from the silicon surface by the BHF process. However, the bonding strength was deteriorated by the anomalous Pd precipitation due to the above-described surface defects. Therefore, according to the working examples, it is possible to easily provide a high-efficient multi-junction solar cell which has the bonding structure excellent in the bonding strength and which is excellent in the cell performance, thereby improving the reliability of the solar cell.

According to the above-described working examples, the electrically-conductive nanoparticles 23 were settled down in the silicon layer without the execution of the process for removing the oxidation region. However, the process for settling down the electrically-conductive nanoparticles 23 may be performed after the process for removing the oxidation region. That is, the presence or absence of the oxidation region is not partially limited, and the intrusion of the electrically-conductive nanoparticles 23 into the silicon layer provides a similar functional effect to that in the above-described working examples.

In addition, in the above-described embodiments, the multi-junction solar cell has been exemplified as the semiconductor device. However, the present embodiments are also applicable to, for example, an optical integrated element or a silicon photonics element in which an Si semiconductor element and a plurality of semiconductor elements are bonded and arrayed in series.

While the present disclosure has been illustrated and described with respect to a particular embodiment thereof, it should be appreciated by those of ordinary skill in the art that various modifications to this disclosure may be made without departing from the spirit and scope of the present disclosure.

1. A semiconductor device comprising:
a first semiconductor element including a silicon layer and having a first bonding surface;
a second semiconductor element having a second bonding surface facing the first bonding surface; and
a plurality of electrically-conductive nanoparticles positioned between the first bonding surface and the second bonding surface and electrically connecting the first semiconductor element and the second semiconductor element to each other,
wherein the plurality of electrically-conductive nanoparticles intrude into the silicon layer.

2. The semiconductor device according to claim 1,
wherein each of the plurality of electrically-conductive nanoparticles contains any one of palladium, gold, silver, platinum, nickel, aluminum, indium, indium oxide, zinc, zinc oxide, and copper.

3. The semiconductor device according to claim 1,
wherein an exposure height of the plurality of electrically-conductive nanoparticles is equal to or less than 20 nm, and
an intrusion height into the silicon layer is equal to or more than 5 nm.

4. A solar cell including the semiconductor device according to claim 1,
wherein the silicon layer of the first semiconductor element contains a semiconductor material made of crystalline silicon or amorphous silicon, and
the second semiconductor element contains one or more of semiconductor materials made of GaAs, AlGaAs, InGaP, AlGaInP, InGaAsP, InGaAs, a chalcogenide-based material, a perovskite-based material, and an organic-based material.

5. A method of manufacturing a semiconductor device comprising steps of:
(a) preparing a first semiconductor element including a silicon layer and having a first bonding surface;
(b) preparing a second semiconductor element having a second bonding surface;
(c) arranging a plurality of electrically-conductive nanoparticles on the first bonding surface;
(d) after the step (c), intruding the plurality of electrically-conductive nanoparticles into the silicon layer; and
(e) after the step (d), facing and pressing the second bonding surface to and against the first bonding surface through the plurality of electrically-conductive nanoparticles therebetween.

6. The method of manufacturing the semiconductor device according to claim 5,
wherein particles made of any one of palladium, gold, silver, platinum, nickel, aluminum, indium, indium oxide, zinc, zinc oxide, and copper are used as the plurality of electrically-conductive nanoparticles.

7. The method of manufacturing the semiconductor device according to claim 5,
wherein an exposure height of the plurality of electrically-conductive nanoparticles is equal to or less than 20 nm, and
an intrusion height into the silicon layer is equal to or more than 5 nm.

8. A method of manufacturing a solar cell including the method of manufacturing the semiconductor device according to claim 5,
wherein a semiconductor material made of crystalline silicon or amorphous silicon is used as the silicon layer of the first semiconductor element, and
one or more of semiconductor materials made of GaAs, AlGaAs, InGaP, AlGaInP, InGaAsP, InGaAs, a chalcogenide-based material, a perovskite-based material, and an organic-based material are used as the second semiconductor element.

9. The method of manufacturing the semiconductor device according to claim 5,
wherein in the step (d), the plurality of electrically-conductive nanoparticles are intruded into the silicon layer by a metal assisted chemical etching method.

10. The method of manufacturing the solar cell according to claim 8,
wherein in the step (d), the plurality of electrically-conductive nanoparticles are intruded into the silicon layer by a metal assisted chemical etching method.
